(19) United States
(12) Patent Application Publication
(10) Pub. No.: US 2008/0283989 A1
(43) Pub. Date: Nov. 20, 2008

(54) Wafer level package and wafer level packaging method

(75) Inventors: Won Kyu Jeung, Seoul (KR); Seog Moon Choi, Seoul (KR); Job Ha, Suwon (KR); Sang Hee Park, Yeongju (KR); Tae Hoon Kim, Suwon (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECANICS CO., LTD., Suwon (KR)

(21) Appl. No.: 12/153,373

(22) Filed: May 16, 2008

(30) Foreign Application Priority Data
May 16, 2007 (KR) 10-2007-47775

(51) Int. Cl. H01L 23/055; H01L 21/54

(52) U.S. Cl. 257/682; 438/113; 257/E23.137; 257/E23.011; 257/E23.19; 257/E21.501; 257/E21.5

(57) ABSTRACT

Provided are a wafer level package and a wafer level packaging method, which are capable of performing an attaching process at a low temperature and preventing contamination of internal devices. In the wafer level package, a device substrate includes a device region, where a device is formed, and internal pads on the top surface. The internal pads are electrically connected to the device. A cap substrate includes a getter corresponding to the device on the bottom surface. A plurality of sealing/attaching members are provided between the device substrate and the cap substrate to attach the device substrate and the cap substrate and seal the device region and the getter. The sealing/attaching members are formed of polymer. A plurality of vias penetrate the cap substrate and are connected to the internal pads. The getter provided in the sealed space defined by the sealing/attaching members can prevent the devices of the device region from being contaminated by moisture or foreign particles generated during the fabrication process, and the sealing/attaching process can be performed at a lower temperature compared with a typical sealing/attaching process using a metal.

### CROSS-REFERENCE TO RELATED APPLICATIONS

This application claims the priority of Korean Patent Application No. 10-2007-47775 filed on May 16, 2007 in the Korean Intellectual Property Office, the disclosure of which is incorporated herein by reference.

### BACKGROUND OF THE INVENTION

1. Field of the Invention

The present invention relates to a wafer level package and a wafer level packaging method, and more particularly, to a wafer level package and a wafer level packaging method, which are capable of performing an attaching process at a low temperature and preventing contamination of internal devices.

2. Description of the Related Art

Recently, as semiconductor devices shrink in size, interest in wafer level package technology is rapidly growing. A wafer level package technology refers to a semiconductor package technology that packages chips at a wafer level where the chips are not cut or separated, as opposing to an existing technology that cuts a wafer into individual chips and packages them.

Specifically, a semiconductor package is fabricated through four steps: circuit design, wafer processing, assembly, and inspection. The assembly process includes a wire bonding process and a packaging process. The assembly process includes cutting a process-finished wafer into individual chips, attaching the individual chips on a small circuit board, bonding wires, and sealing the chips with a plastic package.

The wafer level packaging is accomplished by a simple procedure. That is, instead of plastic that has been used as a package material, a photosensitive insulation material is coated over the individual chips disposed on the wafer, wires are bonded, and an insulation material is again coated thereon.

Such a wafer level package technology can reduce the semiconductor assembly processes, such as the wire bonding and plastic package. Furthermore, a manufacturing cost can be remarkably reduced because the plastic, the circuit board, and the wires, which have been used for the semiconductor assembly, are not needed. In particular, since the wafer level package technology can fabricate the package with the same size as the chip, the package size can be reduced by more than about 20 percents compared with a typical chip scale package (CSP) that has been applied to the shrinkage of the semiconductor package.

As illustrated in FIG. 1, a wafer level package includes a first substrate 1 defining a device active region 4 where a lot of devices are formed. The first substrate 1 is provided for device fabrication. A second substrate 2 is attached to the first substrate 1 through support walls 3 and supported by the support walls 3. The second substrate 2 is provided for capping the device active region 4 in order to protect it. An electrode 5 for an external wire is packaged in such a state that it is arranged on the first substrate 1, without protruding over the silicon substrate 2.

Since the fabrication of such a related art wafer level package requires a high-temperature attaching process, attachment failure may occur when the first substrate 1 and the second substrate 2 have different thermal expansion coefficients. For example, distortion or crack may occur in the attachment surfaces. Therefore, the wafer level package technology according to the related art has a limitation in that the first substrate 1 and the second substrate 2 must be made of the same material or materials having similar thermal expansion characteristics.

Consequently, the second substrate 2 for protecting or sealing the devices of the device active region 4, which are provided in an inner space defined by the support walls 3, must also be made of the same expensive material as the first substrate 1. Hence, there is a limitation in reducing the manufacturing cost, and the processes for dealing with the expensive substrate become complicate.

Furthermore, when polymer is used as a sealing material in the attaching process, external foreign particles and moisture may penetrate into the device active region 4, causing the contamination of the device. To solve this problem, a metal instead of polymer may be used in the attaching process. In this case, however, the fabrication process is complicated and the manufacturing cost is increased.

### SUMMARY OF THE INVENTION

An aspect of the present invention provides a wafer level, which is capable of preventing contamination of internal devices, providing excellent attachment characteristic, and simplifying a fabrication process.

Another aspect of the present invention provides a wafer level packaging method, which is capable of performing an attaching process at a low temperature and preventing the contamination of internal devices.

According to an aspect of the present invention, there is provided a wafer level package, including: a device substrate comprising a device region, where a device is formed, and internal pads on the top surface, the internal pads being electrically connected to the device; a cap substrate comprising a getter corresponding to the device on the bottom surface; a plurality of sealing/attaching members provided between the device substrate and the cap substrate to attach the device substrate and the cap substrate and seal the device region and the getter, the sealing/attaching members being formed of polymer; and a plurality of vias penetrating the cap substrate and connected to the internal pads.

According to another aspect of the present invention, there is provided a wafer level packaging method, including: attaching a first wafer for a device substrate to a second wafer for a cap substrate by using a plurality of sealing/attaching members formed of polymer, the first wafer comprising a device region and one or more internal pads on the top surface, the internal pads being electrically connected to device of the device region, the second wafer comprising a getter on the bottom surface facing the device region; performing an etch process using first photoresist patterns, which are provided on the top surface of the second wafer, to form a plurality of via holes exposing the internal pads through the second wafer and the polymer; performing a physical vapor deposition (PVD) process to fill the via holes with a metal, and planarizing the resulting structure to form a plurality of vias; forming a plurality of external pads connected to the vias by using second photoresist patterns, which are provided on the top surface of the second wafer; and performing a dicing process for cutting along scribe lines penetrating external sealing/attaching members sealing the device region, the getter, and the internal pads.

A part of the sealing/attaching members may enclose the vias and the internal pads.

An outer portion of the sealing/attaching member may be formed in a closed-curve shape defining a sealed space enclosing the device region, the getter, and the internal pads.

The device may include a surface acoustic wave (SAW) filter having an interdigital transducer (IDT) electrode.

The getter may be formed of one material selected from the group consisting of barium, magnesium, zirconium, red phosphorus, or titanium.

The polymer of the sealing/attaching member may include a polymer selected from the group consisting of benzocyclobutene (BCB), dry film resin (DFR), epoxy, and thermosetting polymer.

The etching process for forming the plurality of via holes may be performed by a reactive ion etch (RIE) dry etch process to form the via holes in a cylindrical shape.

In the forming of the vias, the PVC process may be performed by a sputtering process for depositing the metal to fill the via holes.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view illustrating a wafer level package according to the related art;

FIG. 2 is a cross-sectional view illustrating a wafer level package according to an embodiment of the present invention; and

FIGS. 3A to 3E are cross-sectional views illustrating a wafer level packaging method according to an embodiment of the present invention.

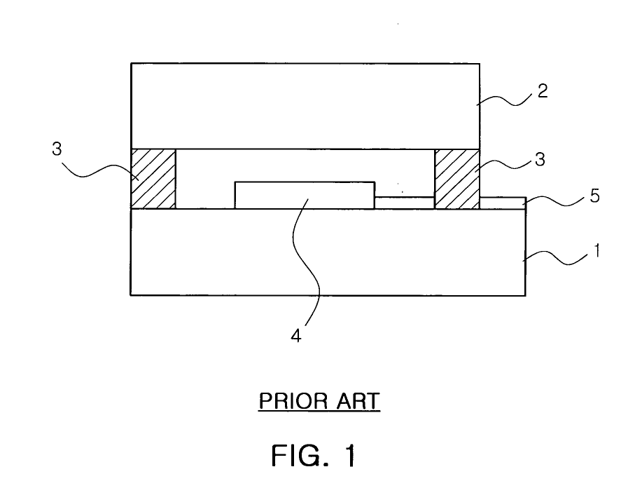

### DETAILED DESCRIPTION OF THE PREFERRED EMBODIMENT

Exemplary embodiments of the present invention will now be described in detail with reference to the accompanying drawings.

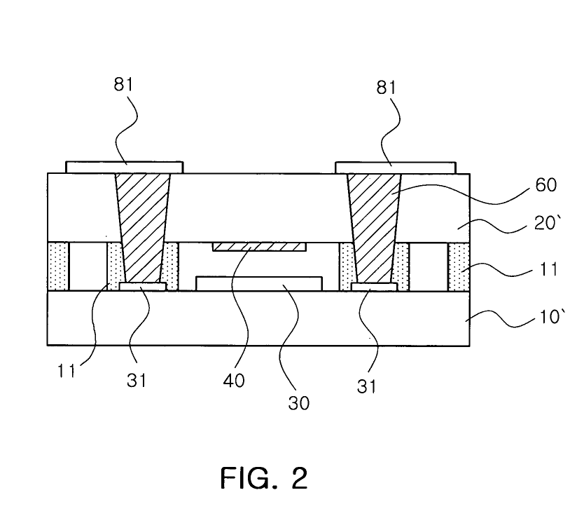

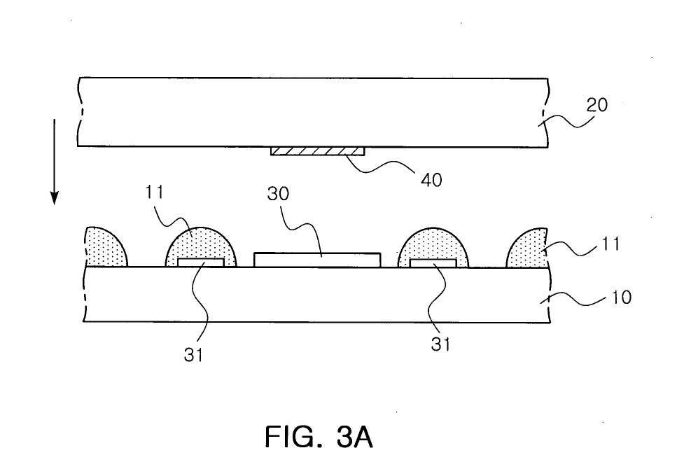

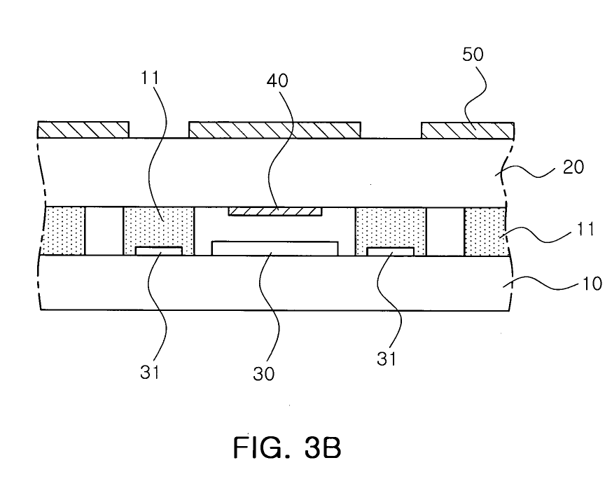

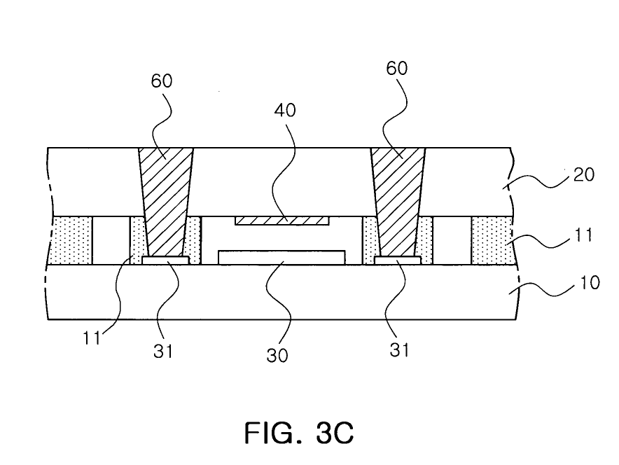

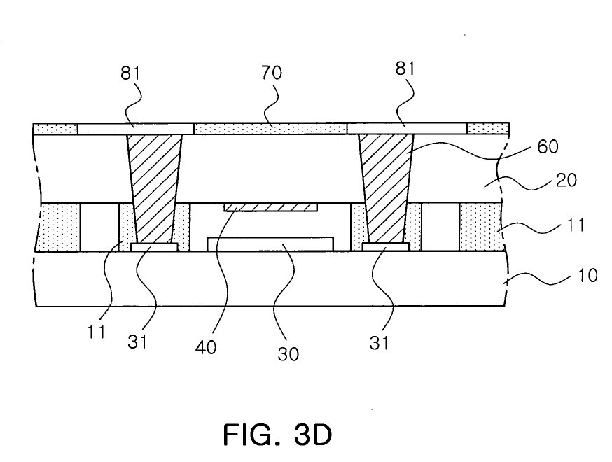

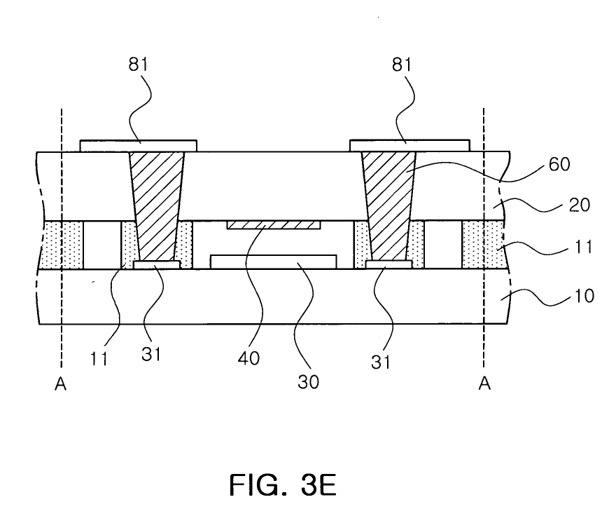

FIG. 2 is a cross-sectional view illustrating a wafer level package according to an embodiment of the present invention, and FIGS. 3A to 3E are cross-sectional views illustrating a wafer level packaging method according to an embodiment of the present invention.

Referring to FIG. 2, the wafer level package according to the embodiment of the present invention includes a device substrate 10′ having a device region 30 on the top surface thereof, a cap substrate 20′, a plurality of sealing/attaching members 11 for attaching and sealing the device substrate 10′ and the cap substrate 20′, a getter 40, a plurality of vias 60 penetrating the cap substrate 20′ and electrically connected to the device region 30, and a plurality of external pads 81 electrically connected to the vias 60.

The device substrate 10′ includes the device region 30 and one or more internal pads 31. A device that must be sealed is formed in the device region 30. Examples of the device include a surface acoustic wave (SAW) filter having an interdigital transducer (IDT) electrode, a micro electro mechanical systems (MEMS) device, and so on. The internal pads 31 are electrically connected to the device of the device region 30.

The sealing/attaching member 11 is formed of polymer, such as benzocyclobutene (BCB), dry film resin (DFR), epoxy, and thermosetting polymer. An outer portion of the sealing/attaching member 11 is formed in a closed-curve shape around the device region 30. The closed-curve shape may be circular or rectangular. An inner portion of the sealing/attaching member 11 encloses the via 60. Since a melting point of the sealing/attaching member 11 is lower than that of a metal, the sealing/attaching member 11 can seal the device of the device region 30 by attaching the device substrate 10′ to the cap substrate 20′ at a low temperature.

The cap substrate 20′ is attached to the device substrate 10′ by the sealing/attaching member 11 formed of polymer. The cap substrate 20′ includes the getter 40 on the bottom surface facing the device region 30 of the device substrate 10′. The getter 11 may be formed of one material selected from the group consisting of barium, magnesium, zirconium, red phosphorus, and titanium. The getter 11 absorbs moisture and prevents penetration of foreign particles into the device.

The via 60 penetrates the cap substrate 20′ and is connected to the internal pad 31 and the external pad 81, which are respectively provided on the top surface of the device substrate 10′ and the top surface of the cap substrate 20′. An electrical signal from the device of the device region 30 electrically connected to the internal pad 31 can be transferred through the via 60, and a voltage can be applied to the device of the device region 30 through the via 60.

In the wafer level package according to the embodiment of the present invention, the getter 40 provided in a sealed space defined by the sealing/attaching members 11 can prevent the device of the device region 30 from being contaminated by moisture or foreign particles generated during the fabrication process. Furthermore, due to the use of the sealing/attaching members 11 formed of polymer, the sealing/attaching process can be performed at a lower temperature than the related art sealing/attaching process using a metal.

A wafer level packaging method according to an embodiment of the present invention will be described below with reference to FIGS. 3A to 3E.

Referring to FIG. 3A, a first wafer 10 for a device substrate is prepared. The first wafer 10 includes a device region 30 and one or more internal pads 31 on the top surface. The internal pads 31 are electrically connected to device of the device region 30. A second wafer 20 for a cap substrate is prepared. The second wafer 20 includes a getter 40 on the bottom surface facing the device region 30. The first wafer 10 and the second wafer 20 are attached by sealing/attaching members 11 formed of polymer. The device region 30 is sealed by curing the sealing/attaching members 11. The device of the device region 30, which is provided on the top surface of the first wafer 10, need to be sealed. For example, the device may be a surface acoustic wave (SAW) filter having an interdigital transducer (IDT) electrode. The SWA filter of the device region 30 is electrically connected to the internal pad 31.

The first wafer 10 and the second wafer 20 are attached by the sealing/attaching members 11 formed of polymer. Since the sealing/attaching member 11 is formed of benzocyclobutene (BCB), dry film resin (DFR), epoxy, or thermosetting polymer, it is melted at 80-150° C., which is lower than a melting point of a metal, and attaches the first wafer 10 to the second wafer 20. Therefore, the thermal deformation and damage of the first and second wafers 10 and 20 due to temperature can be prevented.

Furthermore, the getter 40 disposed on the bottom surface of the second wafer 20 and corresponding to the SAW filter of the device region 30 can prevent the SAW filter of the device region 30 from being contaminated by moisture or foreign particles generated during the attaching process.

Referring to FIG. 3B, after the first wafer 10 and the second wafer 20 are attached by polymer, first photoresist patterns 50 are formed on the second wafer 20, and an etch process is performed to form via holes (not shown) for vias 60 that will be connected to the internal pads 31.

The etch process for forming the via holes using the first photoresist patterns 50 is accomplished by a wet etch process or a dry etch process. In this embodiment, a wet etch process using the photoresist patterns 50 is performed to form the via holes exposing the internal pads 31. An opening size of the via hole may be getting narrower from the second wafer 20 through the sealing/attaching member 11 to the internal pad 31. Alternatively, a reactive ion etch (RIE) dry etch process may be performed to form the via hole that is cylindrical from the wafer 20 through the sealing/attaching member 11 to the internal pad 31.

Referring to FIG. 3C, after the via holes are formed using the first photoresist patterns 50, a physical vapor deposition (PVD) process is performed to fill the via holes with a metal. A chemical mechanical polishing (CMP) process is then performed to planarize the metal filling the via holes and the top surface of the second wafer 20. In this way, the vias 60 are formed. The PVD process for forming the vias 60 illustrated in FIG. 3C may be performed by a sputtering process that deposits a metal, such as aluminum (Al) or copper (Cu), to fill the via holes exposing the internal pads 31.

Referring to FIG. 3D, after forming the plurality of vias 60 planarized by the CMP process, a photoresist is formed on the second wafer 20 and then patterned to form second photoresist patterns 70 for forming external pads 81 that will be connected to the vias 60.

After forming the second photoresist patterns 70, a PVD process such as a sputtering process is performed on the top surface of the second wafer 20, where the second photoresist patterns 70 are formed, to deposit a metal between the second photoresist patterns 70, thereby filling an interval between the second photoresist patterns 70. Then, planarization is performed by a CMP process.

Referring to FIG. 3E, after depositing the metal between the second photoresist patterns 70 and performing the CMP process thereon, an ashing process for removing the second photoresist patterns 70 and a cleaning process are performed to form external pads 81 on the second wafer 20.

As illustrated in FIG. 3E, after forming the external pads 81 on the second wafer 20, a dicing process is performed to cut along scribe lines A in order to separate the semiconductor device into packages sealing the SAW filter of the device region 30.

As illustrated in FIG. 2, after the dicing process for cutting along the scribe lines A, a wafer level package where the SWA filter of the device region 30 is sealed by the sealing/attaching member 11 formed of polymer can be provided. It is possible to prevent the deformation or crack due to high temperature when attaching the first wafer 10 and the second wafer 20 having different thermal expansion coefficients.

As described above, the present invention can provide the wafer level package, in which the getter provided in the sealed space defined by the sealing/attaching members can prevent the devices of the device region from being contaminated by moisture or foreign particles generated during the fabrication process, and the sealing/attaching process can be performed at a lower temperature compared with the related art sealing/attaching process using a metal.

Moreover, the present invention can provide the wafer level packaging method, in which the getter provided in the sealed space defined by the sealing/attaching members can prevent the devices of the device region from being contaminated by moisture or foreign particles generated during the fabrication process, and the sealing/attaching process can be performed at a lower temperature compared with the related art sealing/attaching process using a metal. Therefore, it is possible to prevent the deformation or crack due to high temperature when attaching the wafers having different thermal expansion coefficients.

While the present invention has been shown and described in connection with the exemplary embodiments, it will be apparent to those skilled in the art that modifications and variations can be made without departing from the spirit and scope of the invention as defined by the appended claims.

1. A wafer level package, comprising:
a device substrate comprising a device region, where a device is formed, and internal pads on the top surface, the internal pads being electrically connected to the device;
a cap substrate comprising a getter corresponding to the device on the bottom surface;
a plurality of sealing/attaching members provided between the device substrate and the cap substrate to attach the device substrate and the cap substrate and seal the device region and the getter, the sealing/attaching members being formed of polymer; and
a plurality of vias penetrating the cap substrate and connected to the internal pads.

2. The wafer level package of claim 1, further comprising a plurality of external pads provided on the top surface of the cap substrate in order for electrical connection to the vias.

3. The wafer level package of claim 1, wherein a part of the sealing/attaching members enclose the vias and the internal pads.

4. The wafer level package of claim 1, wherein an outer portion of the sealing/attaching member is formed in a closed-curve shape defining a sealed space enclosing the device region, the getter, and the internal pads.

5. The wafer level package of claim 1, wherein the device comprises a surface acoustic wave (SAW) filter having an interdigital transducer (IDT) electrode.

6. The wafer level package of claim 1, wherein the getter is formed of one material selected from the group consisting of barium, magnesium, zirconium, red phosphorus, or titanium.

7. The wafer level package claim 1, wherein the polymer of the sealing/attaching member comprises a polymer selected from the group consisting of benzocyclobutene (BCB), dry film resin (DFR), epoxy, and thermosetting polymer.

8. A wafer level packaging method, comprising:
attaching a first wafer for a device substrate to a second wafer for a cap substrate by using a plurality of sealing/attaching members formed of polymer, the first wafer comprising a device region and one or more internal pads on the top surface, the internal pads being electrically connected to device of the device region, the second wafer comprising a getter on the bottom surface facing the device region;
performing an etch process using first photoresist patterns, which are provided on the top surface of the second wafer, to form a plurality of via holes exposing the internal pads through the second wafer and the polymer;
performing a physical vapor deposition (PVD) process to fill the via holes with a metal, and planarizing the resulting structure to form a plurality of vias;
forming a plurality of external pads connected to the vias by using second photoresist patterns, which are provided on the top surface of the second wafer; and
performing a dicing process for cutting along scribe lines penetrating external sealing/attaching members sealing the device region, the getter, and the internal pads.

9. The wafer level packaging method of claim 8, wherein a part of the sealing/attaching members enclose the vias and the internal pads.

10. The wafer level packaging method of claim 8, wherein the forming of the vias comprises planarizing the top surface of the second wafer by performing a chemical mechanical polishing (CMP) process on the metal filling the via holes.

11. The wafer level packaging method of claim 8, wherein, in the attaching process using the plurality of sealing/attaching members, an outer portion of the sealing/attaching member is formed in a closed-curve shape defining a sealed space enclosing the device region, the getter, and the internal pads.

12. The wafer level packaging method of claim 8, wherein the getter is formed of one material selected from the group consisting of barium, magnesium, zirconium, red phosphorus, or titanium.

13. The wafer level packaging method of claim 8, wherein the polymer of the sealing/attaching member comprises a polymer selected from the group consisting of benzocyclobutene (BCB), dry film resin (DFR), epoxy, and thermosetting polymer.

14. The wafer level packaging method of claim 8, wherein the etching process for forming the plurality of via holes is performed by a reactive ion etch (RIE) dry etch process to form the via holes in a cylindrical shape.

15. The wafer level packaging method of claim 8, wherein, in the forming of the vias, the PVC process is performed by a sputtering process for depositing the metal to fill the via holes.

16. The wafer level packaging method of claim 8, wherein the device comprises a surface acoustic wave (SAW) filter having an interdigital transducer (IDT) electrode.

17. The wafer level package of claim 2, wherein a part of the sealing/attaching members enclose the vias and the internal pads.

18. The wafer level package of claim 2, wherein an outer portion of the sealing/attaching member is formed in a closed-curve shape defining a sealed space enclosing the device region, the getter, and the internal pads.

19. The wafer level package of claim 2, wherein the device comprises a surface acoustic wave (SAW) filter having an interdigital transducer (IDT) electrode.

20. The wafer level package of claim 2, wherein the getter is formed of one material selected from the group consisting of barium, magnesium, zirconium, red phosphorus, or titanium.
